(19) United States
(12) Patent Application Publication
(10) Pub. No.: US 2003/0028839 A1
(43) Pub. Date: Feb. 6, 2003

(54) Methods and devices for converting as well as decoding a stream of data bits, signal and record carrier

(76) Inventors: Willem Marie Julia Marcel Coene, Eindhoven (NL); Charalampos Pozidis, Gattikon (CH); Johannes Wilhelmus Maria Bergmans, Eindhoven (NL)

Correspondence Address: Philips Electronics North America Corp., 580 White Plains Road, Tarrytown, NY, 10591, US

(21) Appl. No.: 10/113,043

(22) Filed: Apr. 1, 2002

(30) Foreign Application Priority Data
Mar. 30, 2001 (GB) 0107950.8
Sep. 11, 2001 (EP) 01203428.6

(51) Int. Cl. H03M 13/00

(52) U.S. Cl. 714/758

(57) ABSTRACT

The invention relates to methods and devices for converting a stream of data bits of a binary information signal 2 into a stream of data bits of a constrained binary channel signal 3 using multiple channel codes Cₛₜ, C_{pc}. Apart from a standard code Cₛₜ, that is designed for a high coding rate, a parity-check enabling code C_{pc} is used that allows realization of a certain, predefined parity-check constraint imposed on the constrained binary channel signal 3. This parity-check constraint is related to a predetermined error event of the channel. The amount of use of the parity-check enabling code C_{pc} is dependent on the need for preventing the certain error event. Also another channel code C_{sub} can be used in this method in order to realise DC-control.

The invention further relates to a corresponding signal, record carrier as well as a method and device for decoding.

The invention relates to a method and a device for converting/encoding a stream of data bits of a sequence of consecutive user words of a binary information signal into a stream of data bits of a sequence of consecutive channel words of a constrained binary channel signal as well as to a method and a device for decoding a stream of data bits of a sequence of consecutive channel words of a constrained binary channel signal into a stream of data bits of a sequence of consecutive user words of a binary information signal. Furthermore, the invention relates to a signal comprising a stream of data bits of a constrained binary channel signal, obtained after carrying out such a method as well as a record carrier on which such a signal is recorded.

In the traditional coding scheme for storage channels, the blocks of error-correction coding (ECC) and modulation coding have no common functionality. The modulation code is typically a run-length limited (RLL) code, characterized by its dk constraints, and is designed to improve the bit-detection performance in the regime of severe intersymbol interference, and to enable timing recovery. The ECC code is typically a (byte-based) Reed-Solomon code, and has to deal with all the errors of the channel, that is, random errors that arise due to imperfections in the bit-detection process, which derives the channel bit-stream from the signal waveform, and burst errors due to scratches, dust etc. on the disc surface.

Random errors most often take the form of a shift of a transition in the RLL channel bit-stream over a distance of one bit. Such errors are thus very localized and lead, after demodulation, to only one (or two) erroneous symbol(s) (bytes) that are to be corrected by the ECC decoder. Correction of a single erroneous symbol (byte) by the ECC decoder requires a redundancy of two parity symbols (bytes). On the other hand, inclusion of parity-checks at the level of the channel bit-stream can yield equivalent error correction performance for random errors, but at a much lower overhead.

It was realized that a combination of error correction coding and modulation coding may be quite advantageous in terms of overall efficiency and performance, and since then the subject became quite popular in the coding literature, e.g. Y. Saitoh, I. Ibe, H. Imai, “Peak-Shift and Bit Error-Correction with Channel Side Information in Runlength-Limited Sequences”, 10th Int. Symp. Applied Algebra, Algebraic Algorithms and Error-Correcting Codes, vol. AAECC-10, pp. 304-315, 1993; and P. Perry, M.-C. Lin, Z. Zhang, “Runlength-Limited Codes for Single Error-Detection with Mixed Type Errors”, IEEE Trans. Inform. Theory, vol. 44, pp. 1588-1592, July 1998.

Parity-check coding focuses on the most prominent error patterns that are left by the bit-detector. For the magnetic recording channel, parity-check coding as reported in Perry et al (cf. above) considers the situation where the dk bit-stream is recorded on the disc. The dk bit-stream has ‘1’-bits at the position of transitions, and ‘0’-bits elsewhere. One of the most prominent type of random errors for the magnetic recording channel are peak-shift errors, where the ‘1’-bits are shifted (to the left or right), and drop-in and drop-out errors, where a ‘0’ becomes a ‘1’, or vice versa. For the optical recording channel, the dk bit-stream is passed through a 1T-precoder, which is an integrator modulo 2, which yields the RLL bitstream that is written on the disc. As a result, the RLL bit-stream has ‘1’-bits at marks (or pits) and ‘0’-bits at non-marks (or lands). In optical recording, the most prominent random errors are transition shifts, which cause the run-lengths at the left and right side of the transition to become one (or more) bit(s) longer and shorter, respectively. Due to the 1T-precoder between the dk bit-stream and the RLL bit-stream, the transition error in the RLL bit-stream is identical to a peak-shift error in the dk bit-stream.

A RLL coding scheme with error-detection or error correction capability is described by Perry et al (cf. above): the channel bit-stream resulting from the RLL encoder is parsed into information segments of a fixed length. Between each pair of information segments, a parity block is inserted. The combination of an information segment with the subsequent parity block is called a code segment. By construction, this coding scheme (hereafter called parsing scheme) is of the systematic type, that is, the information part is separate from the parity part. The following properties need to be satisfied: the concatenation of the parity block with the preceding and subsequent information segments may not violate the RLL constraints; and the parity block has to enable error-control via a parity-check constraint that must have a predetermined value for each code segment.

Perry et al (cf. above) considered mixed-type errors for the magnetic recording channel, that is, the error can be a single-bit shift error, or a drop-out or drop-in error. They showed that for detection of a single mixed-type error, parity blocks with a length of 2d+3 channel bits are required.

The major advantage of the parsing scheme is its simple and systematic structure. The overhead, measured in terms of user bits, for detection of a single error equals (2d+3) R, with R being the rate of the RLL code. Location of the error is performed by using channel side information as being disclosed by Saitoh et al (cf. above). Compared to the overhead needed for correction of a random error by a standard ECC, which equals two parity bytes, the parsing scheme needs about a factor of 4.5 less overhead.

Concatenated parity-check coding is yet another RLL coding scheme with error-detection or error-correction capability. It is described in S. Gopalaswamy, J. Bergmans, “Modified Target and Concatenated Coding for d=1 Constrained Magnetic Recording Channels”, Proceedings of the IEEE International Conference on Communications, New Orleans, USA, Jun. 18-22, 2000, pp. 89-93; H. Sawaguchi, M. Kondou, N. Kobayashi, S. Mita, “Concatenated Error Correction Coding for High-Order PRML Channels”, Proceedings of Globecom 1998, Sidney, pp. 2694-2699; and H. Sawaguchi, S. Mita, “Soft-Output Decoding for Concatenated Error Correction in High-Order PRML Channels”, Proceedings of the IEEE International Conference on Communications, Vancouver, Canada, Jun. 6-10, 1999, pp. 1632-1637.

This scheme considers segments of user data that are encoded with a standard RLL encoder. For each encoded segment, parity-check values are computed. The parity-check bits are separately RLL-encoded and appended to the RLL channel bit-stream of the segment, after which the next segment is encoded. The main advantage of the concatenated parity-check coding scheme (hereafter called concatenated scheme) is its efficiency: a parity-check bit requires 1/C_{d,k} channel bits with C_{d,k} the capacity of the (d,k)-constrained sequences. As an example, for a d=2 RLL code with rate R≈0.5, an efficiency gain with a factor of 3.5 is realized per parity-check bit, compared to the parsing scheme of Perry et al (cf. above).

However, there are two drawbacks. Firstly, it is not possible to check the parity-check constraints directly from the channel bit-stream; instead, it is necessary to demodulate the channel bits corresponding to the parity-check bits first, before any violation of the parity-check constraints of the user-data portion of the channel bit-stream can be inspected. Secondly, the part of the channel bit-stream corresponding to the parity-check bits, is not protected by the parity checks. In the case that a channel error occurs in this part, erro-neous parity-check bits will be demodulated, and those will lead to unwanted corrections in the user-data portion of the channel bit-stream. Hence, due to the parity-check bits being unprotected by the parity checks, there is a possibility of error propagation.

It is therefore an object of the present invention to improve error detection/correction properties of modulation codes.

This object is achieved by providing a method for converting a stream of data bits of a sequence of consecutive user words of a binary information signal into a stream of data bits of a sequence of consecutive channel words of a constrained binary channel signal to be transmitted via a channel, wherein

a) said binary information signal and/or said constrained binary channel signal is divided into channel signal segments, called parity-check segments, wherein each of said parity-check segments is divided into a first part and a second part,

b) said first part is obtained using a code out of a first set of one or more channel codes, said first set comprising a first type of channel code, and

c) said second part is obtained using a code out of a second set of one or more channel codes, said second set comprising at least one second type of channel code being designed as a parity-check enabling code for realising a predefined parity-check constraint imposed on said parity-check segments, wherein said parity-check constraint is related to a predetermined error event of said channel.

It is noted that the term “set of codes” is used in the broadest sense, i.e. such a set may consist of one code only or such a set may consist of a plurality of codes.

The object is further achieved by providing a corresponding device for encoding a stream of data bits of a sequence of consecutive user words of a binary information signal into a stream of data bits of a sequence of consecutive channel words of a constrained binary channel signal according to claims 14 or 15 for performing such a method.

The object is further achieved by providing a signal comprising a stream of data bits of a constrained binary channel signal, obtained after carrying out such a method.

The object is further achieved by providing a record carrier on which such a signal is recorded in a track, in which information patterns represent the signal portions, which information patterns comprise first and second parts, alternating in the direction of the track, the first parts present detectable properties and the second parts present detectable properties distinguishable from the first properties, and the parts having the first properties represent bit cells having the first logical value and the parts having the second properties represent the bit cells having the second logical value.

The object is further achieved by providing a method for decoding a stream of data bits of a sequence of consecutive channel words of a constrained binary channel signal into a stream of data bits of a sequence of consecutive user words of a binary information signal, comprising the step of converting such a signal to a bit string of bits having a first or a second value, said signal containing channel words of length m, where m is equal to m₁ or m is equal to m₂ or m is equal to m₃, said bit string containing the n-bit information words.

It should be noted that in the most general form of the invention the length of the information words used for the different channel codes may also be different from each other.

The object is further achieved by providing a method for decoding a stream of data bits of a constrained binary channel signal into a stream of data bits of a binary information signal according to claims 20 or 21 adapted the above mentioned encoding/converting methods.

The object is further achieved by providing corresponding devices for decoding a stream of data bits of a sequence of consecutive channel words of a constrained binary channel signal into a stream of data bits of a sequence of consecutive user words of a binary information signal according to claims 26 or 27.

According to the present invention an alternative parity-check coding scheme based on a combination of Runlength Limited (RLL) modulation codes is proposed. This coding scheme combines error control with RLL modulation codes. Such a coding scheme is called “combi-code”. It makes use of a combination of RLL codes, similar to the combi-code scheme that was introduced in the framework of DC-free RLL coding in W. Coene, “Combi-Codes for DC-Free Runlength-Limited Coding”, IEEE Trans. Cons. Electr., vol. 46, pp. 1082-1087, November 2000.

The main idea of the present invention is to use a first type of channel code, namely a standard code, particularly a main RLL code together with a second type of channel code, particularly an RLL code, being designed as a parity-check enabling code, i.e. a code allowing to realize a predefined parity-check constraint that is imposed on the channel signal. Thereby, this constraint refers to a predetermined error event.

The parity-check enabling code is used to set the parity-check constraint of a code segment to a predetermined value.

Thus, a parity-check constraint is integrated into the channel code forming an integrated parity-check code, opposite to the state of art parsing scheme and concatenated scheme. This integration achieves a high coding efficiency, and enables to avoid error propagation and hence improves the properties of error correction/detection codes.

Preferably, for DC-control purposes, a third code, the substitution code is used.

Thus, a preferred encoding method is provided, wherein

a) said binary information signal and/or said constrained binary channel signal is divided according to a first division procedure into a first type of channel signal segments and according to a second division procedure into a second type of channel signal segments, being said parity-check segments, both division procedures constituting a repetition scheme of channel codes,

b) said first type channel signal segments are obtained using a first set of channel codes, said first set further comprising a third type of channel code, wherein

b1) said first type of channel code is used for converting data bits of said user words into data bits of said channel words and

b2) said third type of channel code is used for converting data bits of said user words into data bits of said channel words and for realising DC-control on said constrained binary channel signal,

c) said second type channel signal segments are obtained using said second set of channel codes, said second set comprising said first set of channel codes as well as said at least one second type of channel code, and

d) data bits of said user words relating to said first type channel signal segments are encoded with said second type of channel code according to said repetition scheme.

Furthermore, a corresponding device according to claim 16, a corresponding method for decoding according to claim 25 as well as a corresponding device for decoding according to claim 28 are provided.

All three types of codes are jointly constructed, so that the channel words of these codes can be freely concatenated. The repetition scheme indicates whenever one of the user words in one of the second type channel signal segments has to be encoded with one of the channel codes of the second type (C_{pc}). Parity-check coding via combi-codes combines the advantages for the two other schemes, namely simplicity, a high coding efficiency, and no error propagation.

Advantageously, the overhead needed for error correction for the case of single bit transition shift errors (SBTSE) can be reduced down to a single bit by the scheme proposed by the present invention.

Parity-check coding using combi-codes yields a similarly high efficiency as the concatenated scheme, but avoids all of the above mentioned drawbacks. For the application examples, it is focussed on optical recording where single-bit transition-shift errors are the dominant error patterns.

Further advantageous developments are defined in the dependent claims. These and other aspects of the invention will be apparent from and elucidated with reference to the embodiments described herein after with reference to the accompanying drawings, in which:

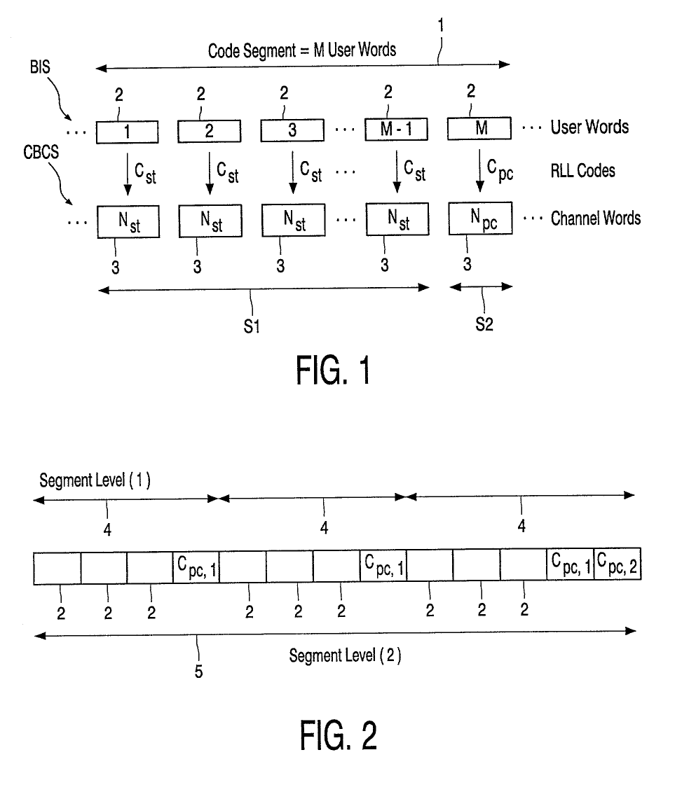

FIG. 1 shows a structure of a code segment consisting of M user words, with the “standard” channel code Cₛₜ for user words 1 up to M−1, and the “parity-check enabling” code C_{pc} for user word M;

FIG. 2 shows a hierarchical parity-check coding scheme (with 2-level hierarchy);

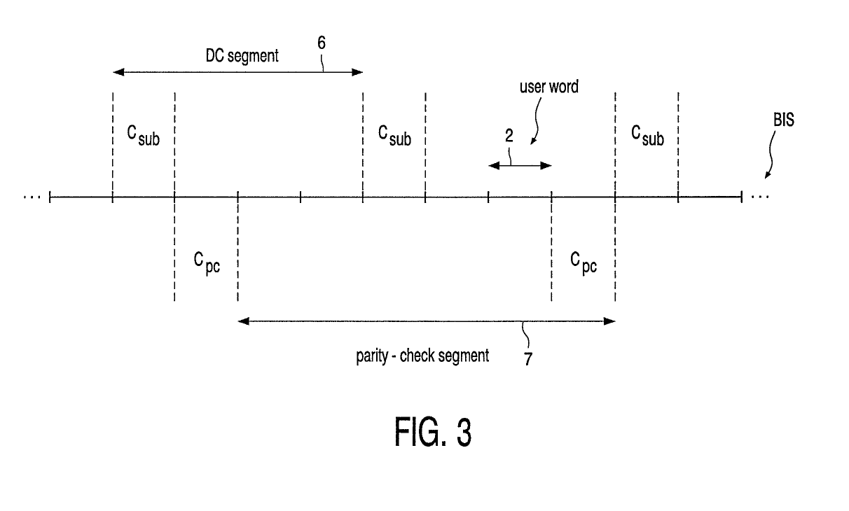

FIG. 3 shows a repetition Scheme of Substitution Code C_{sub} and Parity-Check Enabling Code C_{pc};

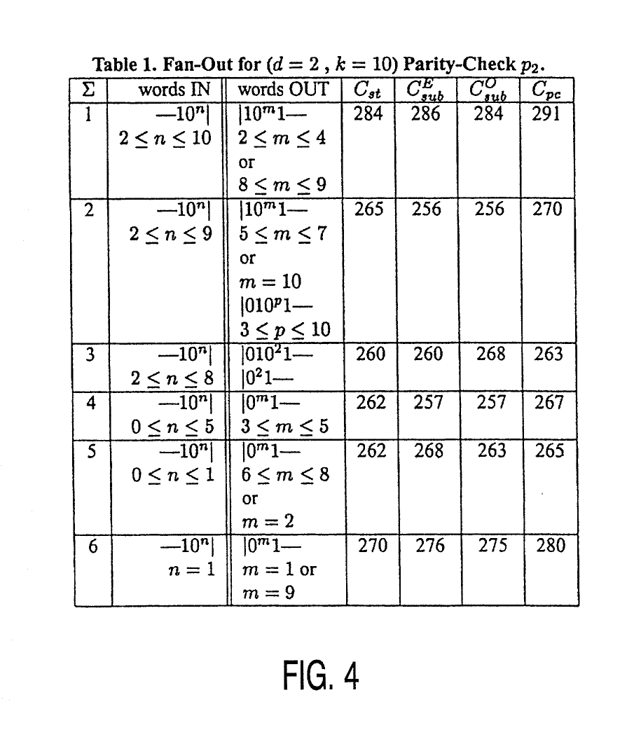

FIG. 4 shows a first table illustrating a Fan-Out of channel words for (d=2, k=10) Parity-Check p₂;

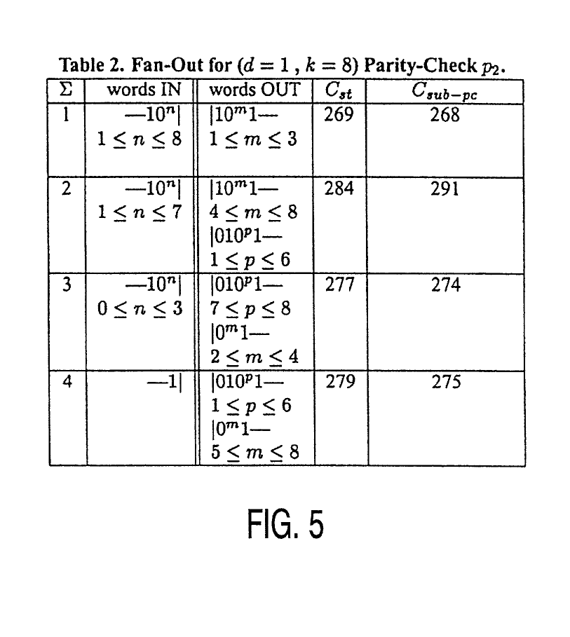

FIG. 5 shows a second table illustrating a Fan-Out of channel words for (d=1, k=8) Parity-Check p₂;

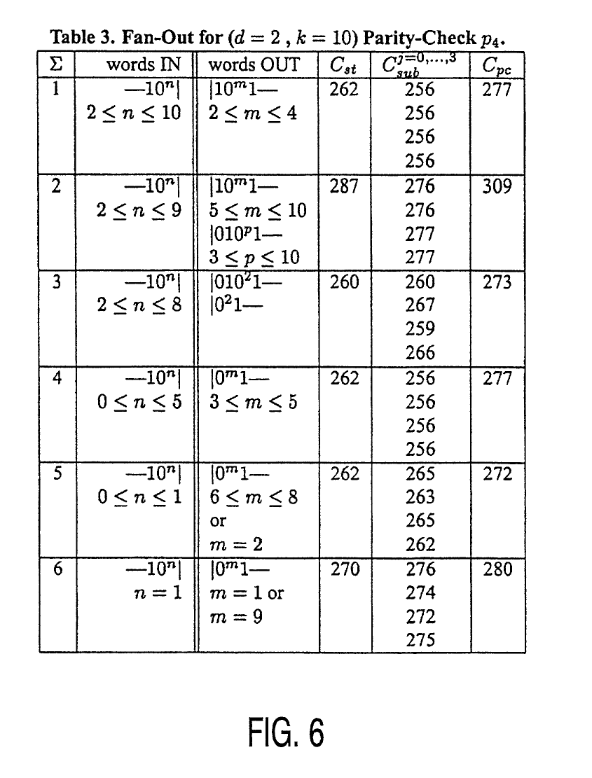

FIG. 6 shows a third table illustrating a Fan-Out of channel words for (d=2, k =10) Parity-Check p₄;

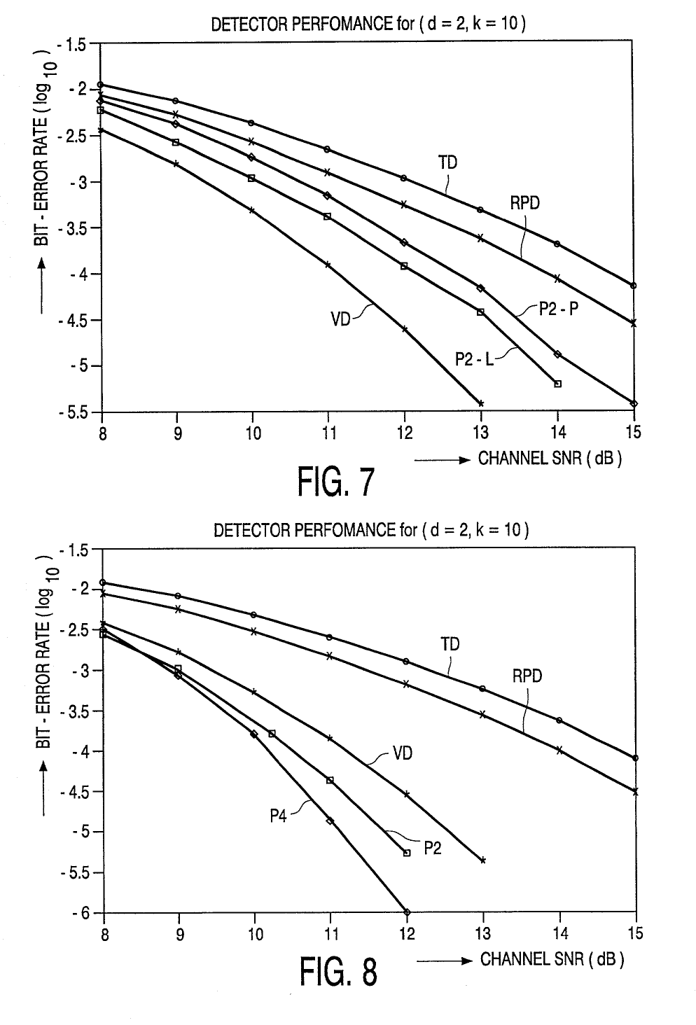

FIG. 7 shows a bit-error-rate performance of various detectors for d=2, k=10 coding; the p₂-scheme is used for SBTSE detection, in cascade with the runlength pushback detection (RPD) bit-detector; phase errors (p₂-P) and local likelihood (P₂-L) are used as channel side information; and

FIG. 8 shows a bit-error-rate performance of various detectors for d=2, k=10 coding; the p₂- and p₄-schemes are used for parity-check decoding, in cascade with the Viterbi bit-detector; only local likelihood is used as channel side information.

The general concept of a parity-check coding scheme with combi-codes is described hereinafter.

Similarly to the coding scheme of Perry et al (cf. above) that is incorporated herein by reference, the present invention proposes to identify code segments in the channel bit-stream, but in our case a code segment is defined as the portion of the channel bit-stream that corresponds with a sequence of M user words (which are usually bytes if the ECC is based on bytes). For each code segment, the present invention wants to realize one or a set of parity-check conditions that apply to the dk-constrained channel bit-stream of that code segment.

In the following, it is focussed on parity checks for bit errors of a single type.

FIG. 1 shows the structure of a code segment 1, called parity-check segment, comprising a stream of data bits of a sequence of consecutive user words 2 of a binary information signal BIS. The parity-check segment 1 is divided into a first part S1 and a second part S2.

The stream of data bits is converted into a stream of data bits of a sequence of consecutive channel words 3 of a constrained binary channel signal CBCS. The scheme according to the present invention involves at least two channel codes Cₛₜ, C_{pc}, which both map complete user words 2 onto the corresponding channel words 3. The first code, denoted by Cₛₜ is a ‘standard’ RLL code, and is designed to have a high coding efficiency. All user words 2, except the last one, are RLL encoded with code Cₛₜ into channel words 3 with a length of Nₛₜ channel bits. Thus, the first part S1 of the parity-check segment 1 is obtained. The second part S2 of the parity-check segment 1 is obtained by a special code, namely a parity-check enabling code denoted by C_{pc}. This code is only used for the last user word 2 in the parity-check segment 1. Thus, the second part S2 comprises one channel word only. The channel word 3 for CPC has a length of N_{pc} channel bits.

Code C_{pc} maps a user word 2 into a channel word 3 that is one word out of a set of channel words 3. The set of channel words 3 comprises at least two channel words 3 for each parity-check condition that needs to be satisfied. The selection of the actual channel word 3 to be encoded is aimed to set the parity-check condition for the complete code segment 1 to a predetermined value.

A hierarchical scheme for parity-check coding is described hereinafter; it is used for more than a single type of bit errors.

In general, the bit-errors that are generated upon bit-detection, are not of a single type. The scheme of FIG. 1 deals only with the most prominent bit-error pattern. In an hierarchical scheme for parity-check coding, the present invention deals with a set of dominant error events, and orders them according to their probability of occurrence. For example, in d=2 RLL coding, the most prominent error patterns left behind by a run-length-pushback bit-detector (see e.g. EP 0 885 499 A2; and T. Nakagawa, H. Ino and Y. Shimpuku, “A Simple Detection Method for RLL Codes (Run detector)”, IEEE Trans. on Magnetics, vol. 33, no. 5, pp. 3262-3264, September 1997, both being incorporated herein by reference) are:

single-bit transition-shift errors, and

shifted 3T (minimum run-length) errors.

FIG. 2 shows a hierarchical parity-check coding scheme. The case is considered, for the sake of simplicity, with the most and the second most probable error event. For both types of error events a parity-check condition can be designed, and the related parity-check enabling codes, C_{pc,1} and C_{pc,2} respectively, can be constructed. C_{pc,1} and C_{pc,2} represent the parity-check enabling codes for the most prominent and second most prominent types of error events; the user words 2 for which no code is indicated, are to be encoded with the “standard” code, Cₛₜ. Since the probability of the second error-pattern may be (much) lower than that of the first error-pattern, it is desirable to apply parity-check condition (1) on shorter segments 4 than parity-check condition (2) which is applied on the longer segments 5. Therefore, a hierarchy of parity-check segments is defined, one level being protected by C_{pc,1}, and the second level being protected by C_{pc,2}. Such a 2-level hierarchical scheme is shown in FIG. 2. A segment 5 of level (2) consists of a number of segments 4 of level (1), after which the channel word 3 for the byte encoded with the second parity-check code C_{pc,2} is concatenated.

Various decoding strategies may be devised, dependent on the parity-check condition for C_{pc,1} and C_{pc,2}. If the two parity-check conditions are orthogonal, then the order of decoding does not matter. If they are not orthogonal (like the parity-checks p₂ and p₄ described in the present invention), then it is advantageous to decode parity-check code C_{pc,1} for each segment 4 of level (1) first, prior to decoding of parity-check code C_{pc,2} on the segment 5 of level (2). More complex decoding strategies are possible and within the scope of the attached claims.

A parity-check value for detection of a single single-bit transition-shift error (SBTSE) is described hereinafter. A scheme without DC-control is described first.

First, the situation without DC-control is described to simplify the discussion. In the next section, a combination of DC-control and parity-check coding will be discussed. For detection of a single single-bit transition-shift error (SBTSE), it is proposed to use as a parity-check condition the value p₂ defined over a code segment of N channel bits bᵢ (in dk-notation, with ‘1’-s indicating the transitions):

$${p}_{2} = mod [ {\sum }_{i = 0}^{N - 1} {ib}_{i} , 2 ] . \qquad ( 1 )$$

It can readily be seen that p₂ equals the number of transitions at odd bit positions, modulo 2. As a convention, the first bit of a code segment is defined to have index ‘0’. At the encoder, p₂ is defined to have a predetermined value, say zero, for each code segment. The value of p₂ for the complete code segment is the contribution to p₂ for the first M−1 channel words plus the contribution to p₂ for the last (M-th) channel word. Therefore, the value of p₂ for the complete code segment can be driven to zero via the choice of the channel word for the parity-check enabling code C_{pc} (that is used for the last (M-th) user word).

In the following the error-detecting capability of this parity-check condition will be demonstrated. Assume that in the bit-detection process a single-bit transition-shift error has occurred at a transition that was originally (at the encoder side) odd-indexed, so that it is now detected as even-indexed. Then, the number of odd-indexed transitions (N₀) is reduced by one, and the number of even-indexed transitions (Nₑ) is augmented by one, accordingly. If the erroneous transition was originally even-indexed, the situation is reversed. Evaluation of the parity-check condition p₂ on the as-detected bit-stream will yield p₂=1 for the code segment, which is an error-flag, indicating that an error has occurred. However, there is no indication about the location of the shifted transition. In order to locate the error, use of channel side information can be made as will be discussed below.

It should also be noted that in case two transition-shift errors have occurred during bit-detection, the parity-check yields p₂=0, so that no errors are detected. However, the probability of occurrence of two such errors is substantially lower than that of a single error event.

In the following the effect is described of the position of the channel words of C_{pc} in the parity-check segment, that is, whether the first bit of the word is located at an even-indexed or odd-indexed position. The parity-check code C_{pc} (for SBTSE) has a set of (at least) two channel words, denoted by W₁ and W₂, for each user word. Let bᵢ¹ and b₁² represent the dk channel bits of these two words. The length of the words is equal to N_{pc} channel bits. These words must have opposite contributions to the parity-check value. These contributions depend on whether the channel word of C_{pc} starts at an even-indexed or odd-indexed bit-position in the code segment, and they are given by:

$$\begin{matrix}{p}_{2 , E}^{{W}_{j}} = mod [ {\sum }_{i = 0}^{{N}_{pc} - 1} {ib}_{i}^{j} , 2 ] , and & ( 2 ) \\ {p}_{2 , O}^{{W}_{j}} = mod [ {\sum }_{i = 0}^{{N}_{pc} - 1} ( i + 1 ) {b}_{i}^{j} , 2 ] . & ( 3 )\end{matrix}$$

Obviously, the parity-check contributions with the words starting at even-indexed or odd-indexed bit-positions are related by:

$${p}_{2 , O}^{{W}_{j}} = mod [ {p}_{2 , E}^{{W}_{j}} + {p}^{{W}_{j}} , 2 ] , \qquad ( 4 )$$

with p^{Wj} the parity of the channel word Wⱼ, defined by:

$${p}^{{W}_{j}} = mod [ {\sum }_{i = 0}^{{N}_{pc} - 1} {b}_{i}^{j} , 2 ] . \qquad ( 5 )$$

For a fixed length of the code segments in a format, a single C_{pc} code (with its first bit always located either at an even or odd position) is sufficient. However, in the case that the code segments may vary in length, it may occur that codes C_{pc} are needed for both even and odd first-bit positions. Two separate codes may be used for this purpose, one for p_{2,E}^{W}^{ⱼ}, and one for p_{2,O}^{W}^{ⱼ}. These two codes can be merged into a single code C_{pc} if an extra design criterion is included. In this way, the code C_{pc} becomes independent of the index of the first bit of its words in the parity-check segment. The extra design criterion is that both words of the code C_{pc} that belong to the same user word, have, apart from the opposite contributions to the parity-check value, the same parity value. In such case, it becomes irrelevant if the first bit of the channel words Wⱼ in the code segment is at an even or an odd position. The characteristics of the channel words of the word-pair of the code C_{pc} can be specified in terms of the number of transitions in each word, at odd (n_{O}^{j}) and even (n_{E}^{j}) position, given by:

$$\begin{matrix}{n}_{E}^{j} = mod [ {\sum }_{i = 0}^{⌈ \frac{{N}_{pc}}{2} ⌉ - 1} {b}_{2 i}^{j} , 2 ] and & ( 6 ) \\ {n}_{O}^{j} = mod [ {\sum }_{i = 0}^{⌊ \frac{{N}_{pc}}{2} ⌋ - 1} {b}_{2 i + 1}^{j} , 2 ] & ( 7 )\end{matrix}$$

Using these parameters, the parity and parity-check values result to:

$$\begin{matrix}{p}^{{W}_{j}} = mod [ {n}_{E}^{j} + {n}_{O}^{j} , 2 ] , & ( 8 ) \\ {p}_{2 , E}^{{W}_{j}} = {n}_{O}^{j} , & ( 9 ) \\ {p}_{2 , O}^{{W}_{j}} = {n}_{E}^{j} . & ( 10 )\end{matrix}$$

For the merged version of the code C_{pc}, the two channel words of each word-pair must have opposite parity-check values, and thus opposite values of both n_{E}^{j} and n_{O}^{j} according to Eqs. (9) and (10), and as a result they have the same parity from Eq. (8). The latter property is convenient in view of a combi-code with a substitution code for DC-control, as discussed in the next section.

A scheme with DC-control is described next, whereby reference is made to FIG. 3. FIG. 3 shows a sequence of consecutive user words 2 of a binary information signal BIS. This sequence, which has as a counterpart on the channel side a sequence of consecutive channel words of a constrained binary signal, is divided according to a first division procedure into first type channel signal segments 6 and according to a second division procedure into second type channel signal segments 7, namely parity-check segments. Both division procedures constitute a repetition scheme of channel codes C_{sub}, C_{pc} as well as Cₛₜ (not shown).

DC-control may be realized via a combi-code with a main code or standard code Cₛₜ and a substitution code C_{sub} as described in Coene, “Combi-Codes for DC-Free Runlength-Limited Coding” (cf. above) that is incorporated herein by reference. For p₂ parity-check coding, the combi-code has to deal with a third type of code, the parity-check enabling code C_{pc}. The repetition schemes of C_{sub} and C_{pc} do not have to be the same: for instance, DC-control may be needed more frequently than parity-check control, and the repetition scheme can even be irregular instead of periodic.

A typical scheme with different repetition frequencies for C_{pc} and C_{sub} is shown in FIG. 3. Each segment with DC control, referred as DC segment 6, comprises exactly one user word 2 to be encoded with a substitution code C_{sub} and a number (possibly being zero) of user words 2 to be encoded with a code different from the substitution code C_{sub}. A DC segment 6 starts for example with a user word 2 to be encoded with a substitution code C_{sub}. Each segment with parity-check properties, referred as parity-check segment 7, comprises at least one user word 2 to be encoded with a parity-check enabling code C_{pc} and a number (possibly being zero) of user words 2 that are not to be encoded with a parity-check enabling code C_{pc}. A parity-check segment 7 ends for example with a user word to be encoded with a parity-check enabling code C_{pc}.

The additional requirements that are to be imposed on the substitution code C_{sub}, if it is to be combined with a parity-check enabling code C_{pc} for p₂, will be described hereinafter. In the original proposal of the combi-code, for DC-control only as being described in Coene, “Combi-Codes for DC-Free Runlength-Limited Coding” (cf. above) the substitution code C_{sub} has the property that for each user word 2, there are at least two channel words with opposite parity and with the same next-state in the finite-state machine (FSM) of the sliding block code.

For the combi-code extended with the parity-check code C_{pc}, an additional constraint is imposed: the code words of C_{sub} should have the same parity-check values. With this extra property, the encoding strategy for the combi-code can be as follows:

First, the channel words of C_{pc} are chosen according to its repetition scheme, and using the knowledge of the contribution of the channel words of C_{sub} to the parity-check value (which are by construction the same independent of which of the two words is chosen for C_{sub}).

Next, DC-control with selection of the channel word for C_{sub} is applied, possibly with use of look-ahead, combining subsequent decisions in a decision tree.

It is noted that the parity-check contribution of a channel word depends on the bit-location of its first bit (even- or odd-indexed position). In a general repetition scheme, the words of C_{sub} may be located on both types of positions. Therefore, it is required to construct two versions of the C_{sub} code:

for the even positions, it is needed to keep n_{O}^{j} fixed for the two channel words of each word-pair of C_{sub}^{E}, and

for C_{sub}^{O}, at the odd positions, it is needed to keep n_{E}^{j} fixed.

In conclusion, for a combi-code with a SBTSE parity-check and DC-control, three codes additional to the standard code are needed. Each of the extra codes has a word-pair for each user word. For the two channel words of the word pairs of the substitution codes, it is needed that the words have opposite values of the parity n_{E}^{j}+n_{O}^{j}, and identical values of either n_{O}^{j} or n_{E}^{j} for C_{sub}^{E} and C_{sub}^{O}, respectively. For the (merged version of the) parity check code C_{pc}, identical values of the parity n_{E}^{j}+n_{O}^{j} and opposite values of n_{E}^{j} and n_{O}^{j} are needed simultaneously.

A code design with parity-check p₂ for (d=2, k=10) RLL constraints is described next.

According to an embodiment of the present invention a code with p₂ parity check for EFM-like RLL constraints (d=2, k=10) has been designed. The user words are 8-bit long (byte-oriented coding), and the channel words for Cₛₜ, C_{sub}^{E,O} and C_{pc} have a length of 15, 17 and 17 channel bits, respectively. For the construction of the code use is made of the same approximate eigenvector and the same 6-state finite-state machine (FSM) as used for the EFMCC combi-code, reported in Coene, “Combi-Codes for DC-Free Runlength-Limited Coding” (cf. above).

In principle, the same next-state property that is essential for the substitution code C_{sub}, is not required for the parity-check enabling code C_{pc}. Nevertheless, this property has also been adopted for C_{pc}, because it leads to a deterministic encoding path for a given sequence of user words. Note that with this additional property, the parity-check enabling code can also be used at another word than the last user word in the parity-check segment. The state description of the FSM is given in table 1 according to FIG. 4, together with the fan-out for each state. The fan-out is the total number of words leaving a state. For all codes but the standard code Cₛₜ, the fan-out refers to pairs of channel words.

A code design with parity-check p₂ for (d=1, k=8) RLL constraints is described next.

The overhead needed to accommodate a binary parity-check such as p₂ is one user bit, and equivalently,

$$⌈ \frac{1}{C} ⌉$$

channel bits are needed with C the capacity of the RLL code. For d=2, an overhead of two channel bits is needed for p₂. For d=1, with C_{d=1}=0.6942, the same overhead would apply since

$$⌈ \frac{1}{C} ⌉ = ⌈ 1.44 ⌉ = 2.$$

However, the latter relation also indicates that a minimal overhead of 1.5 channel bits would be feasible. Such an overhead can be realized by use of a time-varying encoder as being described in J. J. Ashley and B. H. Marcus, “Time-Varying Encoders for Constrained Systems: An Approach to Limiting Error Propagation”, IEEE Trans. Inform. Theory, vol. 46, pp. 1038-1043, May 2000 that is incorporated herein by reference, which is equivalent to the virtual use of fractional bits as has been applied in Coene, “Combi-Codes for DC-Free Runlength-Limited Coding” (cf. above) for d=1 in view of an efficient implementation of combi-codes for DC-control.

The disadvantage of a time-varying encoder is that, for each of the phases of the encoder, a separate code is required. For the case of DC-control only, a set of four codes is needed, and for the parity-check p2, an extra set of two codes has to be designed. As an alternative, it is possible to combine the DC-control functionality of the substitution code C_{sub}, and the functionality of the parity-check enabling code C_{pc} for p₂, into one single ‘joint’ code, denoted by C_{sub-pc}, requiring a joint overhead of 3 channel bits, close to the minimal overhead for both parity control and parity-check control. For each byte, the joint code has a set of four channel words, two-by-two having opposite parity, and two-by-two having opposite contributions to the parity-check p2. For d=1, k=8 a combi-code has been designed using a standard code Cₛₜ with 8-to-12 mapping, and a joint code C_{sub-pc} with 8-to-15 mapping. The approximate eigenvector used in the code design is: V_{(d=1, k=8)}={2, 3, 3, 3, 2, 2, 2, 2, 1 }. After a merging-of-states, a 4-state FSM is obtained, as described in table 2 according to FIG. 5.

A parity-check value for detection of one or two single-bit transition-shift error (SBTSE), shifted in the same direction is described hereinafter. A scheme without DC-control is described first.

As another parity-check condition, it is proposed to use the value p₄ defined over a code segment of N channel bits bᵢ (in dk notation):

$${p}_{4} = mod [ {\sum }_{i = 0}^{N - 1} {ib}_{i} , 4 ] . \qquad ( 11 )$$

The p₄ parity check has an overhead of two user bits. A parity-check enabling code C_{pc} is needed in which a byte can be mapped to a channel word out of a quartet of channel words. Each word out of the quartet of channel words has a different contribution to the value of the parity-check p₄. In a parity-check code segment, only the last user word is encoded with the parity-check enabling code C_{pc}. Proper selection of the channel word for the last user word in a segment, out of the quartet of channel words, permits realization of a predetermined value for the parity-check condition p₄, say zero, for the segment.

Different types of errors in the as-detected RLL bit-stream will lead to different values of p₄ as follows: One single-bit transition-shift error will lead to values of p₄=1 or p₄=3(=−1), dependent on whether the transition is shifted to the right or to the left, respectively. A detected value of p₄=2(=−2) indicates that two transitions have been shifted in the same direction, over a distance of a single bit. For the case of d=2 RLL coding, the latter error event almost certainly concerns a shifted minimum run-length (3T).

Note that, in the case of P₄=2, the direction of the shift of the two transitions cannot be determined from the value of the parity-check. A parity-check value of p₄=±1 might in theory also be caused by three simultaneous transition shifts, all in the same direction, but the probability for this to happen in practice is negligible.

Similarly as for p₂, it is described how the parity-check code C_{pc} can be made independent from the index of the first bit of its words in the parity-check segment. The channel words of the four permissible channel words for a given user word are denoted by W₀, W₁, W₂ and W₃. Let bᵢ^{j}, j=0, . . . , 3 represent the dk channel bits of these four words. The length of each of these words is equal to N_{pc} channel bits. The order of the four words of the quartet can always be arranged such that:

$$mod [ {\sum }_{i = 0}^{{N}_{pc} - 1} {ib}_{i}^{j} , 4 ] = j , j = 0 , … ; 3. \qquad ( 12 )$$

Similarly as for the case Of p₂, a single C_{pc} code (with the first bit of its channel word always located at a position with a fixed phase, which is the index of the position modulo 4) is sufficient when the length of the parity-check segments is fixed. However, in the case that the code segments may vary in length, it may occur that different codes C_{pc} are needed for all phases 0, π/2, π and 3π/2 of the first bit position.

By use of an extra design criterion, these four codes can be merged into a single code C_{pc}. A change from one phase to any other possible phase at the first bit of the channel words W₀, W₁, W₂ and W₃ of code C_{pc} results in adapted arguments in the sum of Eq. (12), insofar that the factor i is changed into i+1, or i+2, or i+3, or just remains equal to i. Each of these changes in phase does not have any impact on Eq. (12) on condition that (for the four channel words of a given user word):

$$mod [ {\sum }_{i = 0}^{{N}_{pc} - 1} {b}_{i}^{k} , 4 ] = mod [ {\sum }_{i = 0}^{{N}_{pc} - 1} {b}_{i}^{l} , 4 ] , ∀ k , l = 0 , … , 3. \qquad ( 13 )$$

This implies that the value mod

$$[ {\sum }_{i = 0}^{{N}_{pc} - 1} {b}_{i}^{l} , 4 ]$$

is independent of the word index l of the words of each word quartet, corresponding to a user word. Using the previous condition, one single (merged version of the) code C_{pc} for parity-check p₄ can be constructed. It should also be noted that, because of Eq. (13), the four words of the quartet also have the same parity.

A scheme with DC-control is described next.

As explained in connection with the p₂ parity-check with DC-control, the use of three codes is considered, a standard code Cₛₜ, a substitution code C_{sub} for DC-control, and a parity-check enabling code C_{pc} for parity-check p₄. The regular repetition scheme of FIG. 3 is also considered, with possibly different repetition frequencies for C_{pc}, and C_{sub}. The two channel words of the substitution code are characterized in that both words have opposite parity, and lead to the same next-state in the finite-state machine of the modulation code.

Similarly as for the p₂ case, the two code words of C_{sub} should have the same contributions to the parity-check value p₄ for a given phase j=0, . . . , 3, which is the phase of the first bit of the channel word of C_{sub} in the parity-check code segment. The phase is determined modulo 4. If b_{i,j}^{sub,1} and b_{i,j}^{sub,2} represent the i-th channel bit of the two channel words W₁^{sub} and W₂^{sub} of the word pair of the substitution code C_{sub}, with their first bit located at phase j, the latter condition can be written as:

mod[Σᵢ(i+j)bᵢ^{sub,1},4]=mod[Σᵢ(i+j)bᵢ^{sub,2},4]. (14)

This requirement cannot be fulfilled for two or more phases simultaneously, because the words of the substitution code have opposite parity. Therefore, for every possible phase j of the first bit of the channel words of the substitution code, a separate code C_{sub}^{j} with channel words W_{1,j}^{sub} and W_{2,j}^{sub} for each user word is designed.

A code design with parity-check p₄ for (d=2, k=10) RLL constraints is described next.

According to the present invention a code with p₄ parity check for EFM-like RLL constraints (d=2, k=10) has been designed. The four variants of the substitution code that are needed for the four possible phases of the first bit position of the channel words have been considered. The user words are 8-bit long, and the channel words for Cₛₜ, C_{sub}^{0,1,2,3} and C_{pc} have a length of 15, 17 and 19 channel bits, respectively.

For the construction of the code, the same approximate eigenvector is used as used for p₂; the state description for the 6-state finite-state machine (FSM) is slightly different than used for the design of the code in table 1 according to FIG. 4, which is related to that of the EFMCC combi-code as reported in Coene, “Combi-Codes for DC-Free Runlength-Limited Coding” (cf. above).

In principle, the same next-state property that is essential for the substitution code C_{sub}, is not required for the parity-check enabling code C_{pc}. Nevertheless, this property is adopted also for C_{pc}, because it leads to a deterministic encoding path for a given sequence of user words. The state description of the FSM is given in table 3 according to FIG. 6, together with the fan-out for each state. Only for the standard code Cₛₜ, the fan-out refers to a single channel word. For the substitution code C_{sub}^{0,1,2,3}, the fan-out refers to pairs of channel words, and for the parity-check enabling code C_{pc}, the fan-out refers to quartets of channel words. For the four variants of the substitution code, the fan-out is listed as successive numbers forj=0, . . . , 3 in a single column.

A parity-check value for detection of up to n single-bit transition-shift errors (SBTSE), shifted in the same direction is described hereinafter.

A generalization of the type of parity-check constraints like p₂ and p₄ of the previous sections can readily be obtained as:

$${p}_{2 n} = mod [ {\sum }_{i = 0}^{N - 1} {ib}_{i} , 2 n ] . \qquad ( 15 )$$

The parity-check condition p₂ₙ has an overhead of log, (2n) user bits. It enables detection of single-bit shifts of up to n transitions in the same direction, and of the common direction of the shift in all cases except for p₂ₙ=n. Such a parity-check is interesting in the case that almost all transition-shift errors are in the same direction, as may be the case for an asymmetric impulse response of the channel. This situation may occur during read-out with tangential disc tilt, and when no adaptive equalization is used.

A procedure for error location via channel side information is described hereinafter.

After bit-detection, the evaluation of the parity-check constraint on the as-detected RLL bit-stream of a parity-check segment permits detection of the occurrence of a SBTS error (for the case of p₂) in that segment. In order to locate the error, channel side information is used as suggested by e.g. Saitoh et al (cf. above) that is incorporated herein by reference.

The channel side information can be derived from alternative information obtained from the signal waveform, e.g. in the form of local likelihood information. This will now be explained in more detail for the case of p₂:

Consider a parity-check segment in which a violation of the parity-check constraint is detected. For each separate transition that occurs in the as-detected channel bit-stream, a shift to left and/or right is considered if allowed by the RLL constraints. For each case of a shifted transition, the likelihood for a local sequence of bits is computed, centered around the shifted transition.

The extent of the local sequence is determined by the span of the channel response (as would be used in a Viterbi detector). The likelihood is derived via summation of branch metrics, computed for the different channel bits in the local sequence. The transition that is suspected to be erroneous, and thus needs to be shifted back again, is the one that yields the highest likelihood.

A second way of using channel side information is to pinpoint the erroneous transition by searching for the transition with the largest phase error (in absolute value), as detected in the phase-locked loop (PLL) during timing recovery. Similar measures to use information from the phase errors are described in EP 0 885 499 A2, that is incorporated herein by reference, in case of a bit detector that corrects run-length violations in the as-detected RLL bit-stream. Such a detector is known as run detector as being described in T. Nakagawa, H. Ino and Y. Shimpuku, “A Simple Detection Method for RLL Codes (Run detector)”, IEEE Trans. on Magnetics, vol. 33, no. 5, pp. 3262-3264, September 1997, that is incorporated herein by reference or run-length-pushback detector (RPD).

For the purpose of the invention, the erroneous transition is then shifted back as indicated by the sign of the phase error. After correction of the shifted transition, the value of p₂ is again equal to zero as it was set at the encoder side, and it can be proceed with the demodulation of the corrected channel bit-stream.

It is obvious that the improvement in bit error-rate due to the use of parity-check coding depends on the quality of the bit-detector that generates the RLL bit-stream. Clearly, it is advantageous to use an RPD detector or even a suboptimal detector with PRML-like performance as being disclosed in W. Coene, H. Pozidis, M. van Dijk, J. Kahlman, R. van Woudenberg, B. Stek, “Channel Coding and Signal Processing for Optical Recording Systems beyond DVD”, Proceedings of The Magnetic Recording Conference, TMRC 2000, San Jose, IEEE Trans. Magn., that is incorporated herein by reference, instead of a simple threshold detector, before the parity-check decoding is applied. It is also possible to apply parity-check decoding after a full-fledged Viterbi detector or PRML (partial-response maximum-likelihood) bit-detector. Some of these situations will be dealt with in the following.

In the following the performance of the proposed parity-check scheme in an optical recording scenario is demonstrated, in particular according to simulation results. To this end, simulated replay signals are generated according to the following linear model:

$${x}_{k} = {\sum }_{i = - ∞}^{∞} {a}_{i} {f}_{k - i} + {n}_{k} = {( a * f )}_{k} + {n}_{k} , \qquad ( 16 )$$

where xₖ are samples of the (simulated) signal coming from the optical drive, aₖ denotes the bipolar RLL channel bits stored on disc, fₖ is the impulse response of the optical recording channel, and nₖ is additive white Gaussian noise (AWGN). It is implicitly assumed that optical read-out is a linear process.

The optical channel impulse responses fₖ is generated according to the Braat-Hopkins model as being disclosed in G. Bouwhuis, J. Braat, A. Huijser, J. Pasman, G. van Rosmalen and K. Schouhamer Immink, Principles of Optical Disc Systems, Adam Hilger Ltd, Bristol, UK, 1985, that is incorporated herein by reference. This means that the Fourier transform of fₖ is given by:

$$F ( Ω ) = \{ \begin{matrix}2 ( {cos}^{- 1} ( \frac{Ω}{Ω c} ) - \frac{Ω}{Ω c} \sqrt{1 - {( \frac{Ω}{Ω c} )}^{2} )} & \vert \frac{Ω}{Ω c} \vert < 1 \\ 0 & \vert \frac{Ω}{Ω c} \vert \geq 1\end{matrix} \qquad ( 17 )$$

where Ω is a normalized measure of frequency (Ω=1 corresponds to the baud-rate 1/T), and Ω_{c} denotes the normalized cut-off frequency of the (low pass) optical channel frequency response. The expression for F(Ω) is only valid in the fundamental interval [−0.5,0.5], and beyond that symmetry applies. For an optical recording system using a laser diode with wavelength λ and a lens with numerical aperture NA, the normalized (spatial) cut-off frequency is given by

$${Ω}_{c} = \frac{2 NA}{λ} T .$$

For the DVD system, with λ=650 nm, NA=0.6 and T=133 nm, one gets Ω_{c}≈0.25.

A channel bit-stream aₖ is used that is generated as a (d=2, k=10) maxentropic RLL sequence. The impulse responses fₖ, used in an embodiment of the present invention, is calculated by taking the inverse Fourier transform of F (Ω) and truncating the resulting response to 21 taps (10 taps around the maximum-amplitude tap).

The replay sequence xₖ is equalized before being sent to the detector. The sequence at the output of the equalizer is given by

yₖ=(X*w)ₖ=(a*f*w)ₖ+(n*w)ₖ=(a*p)ₖ+Uₖ, (18)

where wₖ is the impulse response of the equalizer, pₖ=(f*w)ₖ is the combined (channel and equalizer) response, and Uₖ is filtered noise. The equalizer taps are adaptively adjusted, based on the LMS algorithm, in order to minimize the mean square value of an appropriate error signal. Equalizer adaptation aims at shaping the channel response fₖ to the target response gₖ=[0.29,0.5,0.58,0.5,0.29]. The Fourier transform of this response matches the frequency response of the optical channel F(Ω) quite well, and is chosen for minimal noise enhancement. The sequence yₖ at the equalizer output is applied to a threshold detector (TD) in order to generate estimates of the channel bits aₖ. Violations of the RLL code constraints in the detected bit-stream are then corrected by means of a run-length pushback bit-detector (RPD) as being disclosed in EP 0 885 499 A2 and Nakagawa et al (cf. above).

Firstly, detection has been applied with the parity-check coding for p₂ in cascade with the RPD. The parity-check values p₂ are defined over code segments comprising N=100 channel bits. The relatively low value of N is chosen to minimize the probability of multiple SBTSE's in one segment. An error-flag is raised whenever p₂=1.

The two ways to use channel side information, either by phase errors, or by local likelihood information have been considered. The results of the application of the above-mentioned detectors, and the parity-check detection/correction scheme, to the signal of equation (18) are illustrated in FIG. 7. Shown is the bit-error rate (BER) performance of each scheme as a function of the channel SNR (in dB), which is defined here as SNR=E_{f}/Oₙ², where E_{f} denotes the energy of the channel fₖ, and Oₙ² is the variance of the noise nₖ.

Also shown in FIG. 7 is the performance of the Viterbi detector (VD), which implements partial response maximum likelihood (PRML) detection. With respect to the use of channel side information, it turns out that the use of local likelihood information yields a better performance than the use of phase errors. It is further shown that, for a BER level of 10⁻⁴ (corresponding to 200 errors measured), the parity-check scheme requires 1.75 dB less SNR than the RPD, and 2.5 dB less than the binary slicer (TD), while it lags behind the VD by about 1 dB.

Secondly, detection with the parity-check coding for p₂ in cascade with the Viterbi detector has been applied. These results are shown in FIG. 8. Only local likelihood information is used to locate the errors. Also the parity-check condition p₄, defined over code segments comprising N=200 channel bits (keeping the relative overhead the same as for p₂) has been considered. At a BER level of 10⁻⁴, the p₂ and p₄ parity-check schemes require around 0.75 dB and 1 dB less SNR than the VD, respectively.

Since the complexity of the p₂ and p₄ schemes is minimal in comparison to that of the VD, parity check schemes can be used to provide an attractive performance/complexity trade-off when applied in cascade with a RPD detector. It is noted, for the sake of completeness, that the performance of the RPD and the parity-check schemes can be improved by appropriate choice of the target response gₖ.

In conclusion, according to the present invention, a scheme is proposed for parity-check RLL coding that makes use of a combination of RLL codes. All codes are sliding-block codes, that are preferably applied on symbols of a fixed length in view of reduction of error propagation. Apart from a standard code, that is designed for a high coding rate, a parity-check enabling code that allows realization of a certain parity-check constraint on segments of the channel bit-stream is proposed. This constraint is devised to cope with a particular type of random errors of the channel. Violation of the parity-check constraint permits error detection in a segment of the channel bit-stream.

For error correction, channel side information is preferably used. For correction of a single-bit transition-shift error, parity-check coding may be a factor 16 more efficient than correction via the standard error-correction decoding, using Reed-Solomon codes.

The scheme can further be combined with another code, the substitution code, in order to realize DC-control. Parity-check coding via combi-codes combines the advantages of two other existing schemes, which are the parsing scheme by Perry et al and the concatenation scheme by Gopalaswamy et al (cf. above) that is incorporated herein by reference: simplicity, a high coding efficiency, and no error propagation.

Some practical d=2 and d=1 RLL codes for different parity-check constraints are proposed. In the case that DC-control is needed, the number of separate codes in a combi-code scheme depends on the parity-check constraint, and on the repetition frequencies of substitution code and parity-check enabling code. For instance, for the p₄ parity-check constraint, which enable detection of up to two transition-shift errors in the same direction, and also including DC-control, a maximum of six separate codes may be needed.

1. A method for converting a stream of data bits of a sequence of consecutive user words (2) of a binary information signal (BIS) into a stream of data bits of a sequence of consecutive channel words (3) of a constrained binary channel signal (CBCS) to be transmitted via a channel, wherein
a) said binary information signal (BIS) and/or said constrained binary channel signal (CBCS) is divided into channel signal segments, called parity-check segments (1, 7), wherein each of said parity-check segments (1, 7) is divided into a first part (S1) and a second part (S2),
b) said first part (S1) is obtained using a code out of a first set of one or more channel codes, said first set comprising a first type of channel code (Cₛₜ), and
c) said second part (S2) is obtained using a code out of a second set of one or more channel codes, said second set comprising at least one second type of channel code (C_{pc}) being designed as a parity-check enabling code for realising a predefined parity-check constraint imposed on said parity-check segments (1, 7), wherein said parity-check constraint is related to a predetermined error event of said channel.

2. A method according to claim 1, wherein some of said parity-check segments (1, 7) having a length different than other parity-check segments (1, 7).

3. A method according to claim 1, wherein said first type of channel code (Cₛₜ) being a first runlength limited code.

4. A method according to claim 1, wherein said second type of channel code (C_{pc}) being a second runlength limited code.

5. A method according to claim 1, wherein said second set comprising a number of parity-check enabling codes (C_{pc, 1}, C_{pc, 2}) being used to obtain said constrained binary channel signal (CBCS) of said parity-check segments (1, 7), each of the parity-check enabling codes (C_{pc, 1}, C_{pc, 2}) allowing to realise a different predefined parity-check constraint imposed on said constrained binary channel signal (CBCS), wherein an amount of use of said parity-check enabling codes (C_{pc, 1}, C_{pc, 2}) is dependent on the probability of occurrence of the error events related to the parity-check constraints each of the parity-check enabling codes (C_{pc, 1}, C_{pc, 2}) allows to realise.

6. A method according to claim 1, wherein said second set comprising a number of parity-check enabling codes (C_{pc, 1}, C_{pc, 2}) being used to obtain said constrained binary channel signal (CBCS) of said parity-check segments, (1,7), each of the parity-check enabling codes allowing to realise a different predefined parity-check constraint imposed on said constrained binary channel signal (CBCS), wherein an amount of use of each of the parity-check enabling codes (C_{pc, 1}, C_{pc, 2}) is dependent on the need for recovering from the predetermined error events of the channel.

7. A method according to claim 1, wherein a predetermined error event of said channel is a single-bit transition-shift error (SBTSE).

8. A method according to claim 1, wherein a predetermined error event of said channel is a set of up to n single-bit transition-shift errors (SBTSE) shifted in the same direction.

9. A method according to claim 1, wherein a predetermined error event of said channel is a single minimum-run shift error over a single bit.

10. A method according to claim 1, wherein
a) said binary information signal (BIS) and/or said constrained binary channel signal (CBCS) is divided according to a first division procedure into a first type of channel signal segments (6) and according to a second division procedure into a second type of channel signal segments (1, 7), being said parity-check segments (1, 7), both division procedures constituting a repetition scheme of channel codes (Cₛₜ, C_{sub}, C_{pc}),
b) said first type channel signal segments (6) are obtained using a first set of channel codes (Cₛₜ, C_{sub}), said first set further comprising a third type of channel code (C_{sub}), wherein
i) said first type of channel code (Cₛₜ) is used for converting data bits of said user words (2) into data bits of said channel words (3) and
ii) said third type of channel code (C_{sub}) is used for converting data bits of said user words (2) into data bits of said channel words (3) and for realising DC-control on said constrained binary channel signal (CBCS),
c) said second type channel signal segments (1, 7) are obtained using said second set of channel codes, said second set comprising said first set of channel codes (Cₛₜ, C_{sub}) as well as said at least one second type of channel code (C_{pc}), and
d) data bits of said user words (2) relating to said first type channel signal segments (6) are encoded with said second type of channel code (C_{pc}) according to said repetition scheme.

11. A method according to claim 10, wherein each of said first type channel signal segments (6) has the same length, to be called the first type segment length, and/or wherein each of said second type channel signal segments (7) has the same length, to be called the second type segment length.

12. A method according to claim 11, wherein the first type segment length and the second type segment length are identical.

13. A method according to claim 10, wherein said parity-check enabling code (C_{pc}) is arranged for realising DC-control, wherein said first set of channel codes is only used for converting data bits of said user words (2) into data bits of said channel words (3).

14. A device for converting a stream of data bits of a sequence of consecutive user words (2) of a binary information signal (BIS) into a stream of data bits of a sequence of consecutive channel words (3) of a constrained binary channel signal (CBCS), for performing one of the methods according to any one of the preceding claims.

15. A device for converting a stream of data bits of a sequence of consecutive user words (2) of a binary information signal (BIS) into a stream of data bits of a sequence of consecutive channel words (3) of a constrained binary channel signal (CBCS) to be transmitted via a channel, in particular according to claim 14, comprising
a) dividing means for dividing said binary information signal (BIS) and/or said constrained binary channel signal (CBCS) into channel signal segments, called parity-check segments (1, 7), wherein each of said parity-check segments (1, 7) is divided into a first part (S1) and a second part (S2),
b) first channel code encoding means for encoding data bits of said user words (2) into data bits of said channel words (3) of said first parts (S1) using a code out of a first set of one or more channel codes, said first set comprising a first type of channel code (Cₛₜ), and
c) second channel code encoding means for encoding data bits of said user words (2) into data bits of said channel words (3) of said second parts (S2) using a code out of a second set of one or more channel codes, said second set comprising at least one second type of channel code (C_{pc}) being designed as a parity-check enabling code for realising a predefined parity-check constraint imposed on said parity-check segments (1,7), wherein said parity-check constraint is related to a predetermined error event of said channel.

16. A device according to claim 15,
a) comprising further dividing means being designed for dividing said binary information signal (BIS) and/or said constrained binary channel signal (CBCS) according to a first division procedure into a first type of channel signal segments (6) and according to a second division procedure into a second type of channel signal segments (7), being said parity-check segments (1, 7), both division procedures constituting a repetition scheme of channel codes (Cₛₜ, C_{sub}, C_{pc}) wherein
b) first channel code encoding means being designed to obtain said first type channel signal segments (6) using a first set of channel codes (Cₛₜ, C_{sub}), said first set further comprising a third type of channel code (C_{sub}), wherein
i) said first type of channel code (Cₛₜ) is used for converting data bits of said user words (2) into data bits of said channel words (3) and
ii) said third type of channel code (C_{sub}) is used for converting data bits of said user words (2) into data bits of said channel words (3) and for realising DC-control on said constrained binary channel signal (CBCS),
c) second channel code encoding means being designed to obtain said second type channel signal segments (1, 7) using said second set of channel codes, said second set comprising said first set of channel codes (Cₛₜ, C_{sub}) as well as said at least one second type of channel code (C_{pc}), and
d) said first and/or second channel code encoding means being designed to encode data bits of said user words (2) relating to said first type channel signal segments (6) with said second type of channel code (C_{pc}) according to said repetition scheme.

17. A device according to claim 15 or 16, comprising combining means for combining said encoded segments (6, 7) in order to form said constrained binary channel signal (CBCS).

18. A signal comprising a stream of data bits of a constrained binary channel signal (CBCS), obtained after carrying out one of the methods according to any one of claims 1 to 13.

19. A record carrier on which the signal according to claim 18 is recorded in a track, in which information patterns represent signal portions, which information patterns comprise first and second parts, alternating in the direction of said track, said first parts present detectable properties and said second parts present detectable properties distinguishable from said first properties, and said parts having said first properties represent bit cells having a first logical value and said parts having said second properties represent bit cells having a second logical value.

20. A method for decoding a stream of data bits of a sequence of consecutive channel words (3) of a constrained binary channel signal (CBCS) into a stream of data bits of a sequence of consecutive user words (2) of a binary information signal (BIS), comprising the step of converting a signal according to claim 18 to a bit string of bits having one of a first or a second value, said signal containing channel words of length m, where m is equal to m₁, or m is equal to m₂, or m is equal to m₃, said bit string containing the n-bit information words.

21. A method for decoding a stream of data bits of a sequence of consecutive channel words (3) of a constrained binary channel signal (CBCS) into a stream of data bits of a sequence of consecutive user words (2) of a binary information signal (BIS), in particular according to claim 20, wherein
a) said constrained binary channel signal (CBCS) comprising channel signal segments, called parity-check segments (1, 7), wherein each of said parity-check segments (1, 7) comprising a first part (S1) and a second part (S2),
b) said first part (S1) is decoded by using a code out of a first set of one or more channel codes, said first set comprising a first type of channel code (Cₛₜ), and wherein
c) said second part (S2) is decoded by using a code out of a second set of one or more channel codes comprising at least one second type of channel code (C_{pc}) being designed as a parity-check enabling code for realising a predefined parity-check constraint imposed on said parity-check segments (1, 7), wherein said parity-check constraint is related to a predetermined error event of said channel.

22. A method according to claim 21, wherein
a) the value of said parity-check constraint of said parity-check segment (1, 7) is evaluated from the detected bits from the constrained binary channel signal (CBCS) of said parity-check segment (1, 7), and compared with the value of the parity-check constraint that was imposed on said parity-check segment (1, 7) during the encoding operation and
b) if the detected value of the parity-check constraint differs from the imposed value of the parity-check constraint, then the most likely occurrence of the channel error event is corrected in said parity-check segment (1, 7).

23. A method according to claim 22, wherein the location of the most likely channel error event in said parity-check segment (1, 7) is determined by using channel side information in the form of local likelihood information of the bit-synchronous channel signal waveform.

24. A method according to claim 22, wherein said location of said most likely channel error event in said parity-check segment (1, 7) is determined by using channel side information in the form of phase-errors of signal transitions of the bit-synchronous channel signal waveform as evaluated in a phase-locked loop for timing recovery.

25. A method according to claim 21 or 22, wherein said first type channel signal segments (6) and said second type channel signal segments (7) constituting a repetition scheme of channel codes (Cₛₜ, C_{sub}, C_{pc}), wherein
a) said first type channel signal segments (6) are decoded using a first set of channel codes (Cₛₜ, C_{sub}), said first set further comprising a third type of channel code (C_{sub}), wherein
i) said first type of channel code (Cₛₜ) is used for decoding data bits of said channel words (3) into data bits of said user words (2) and
ii) said third type of channel code (C_{sub}) is used for decoding data bits of said channel words (3) into data bits of said user words (2) and possibly for detecting DC control information in said constrained binary channel signal (CBCS), and wherein
b) said second type channel signal segments (1, 7) are decoded using said second set of channel codes, said second set comprising said first set of channel codes (Cₛₜ, C_{sub}) as well as said at least one second type of channel code (C_{pc}), and
c) data bits of said channel words (3) relating to said first type channel signal segments (6) are decoded with said second type of channel code (C_{pc}) according to said repetition scheme.

26. A device for decoding a stream of data bits of a sequence of consecutive channel words (3) of a constrained binary channel signal (CBCS) into a stream of data bits of a sequence of consecutive user words (2) of a binary information signal (BIS), the device comprising converting means for converting a signal according to claim 18 to a bit string of bits having a first or a second value, the signal containing the m-bit channel words, the bit string containing the n-bit information words.

27. A device for decoding a stream of data bits of a sequence of consecutive channel words (3) of a constrained binary channel signal (CBCS) into a stream of data bits of a sequence of consecutive user words (2) of a binary information signal (BIS), in particular according to claim 26, comprising
a) said constrained binary channel signal (CBCS) comprising channel signal segments, called parity-check segments (1, 7), wherein each of said parity-check segments (1, 7) comprising a first part (SI) and a second part (S2),
b) first channel code decoding means for decoding said first part (S1) by using a code out of a first set of one or more channel codes, said first set comprising a first type of channel code (Cₛₜ), and
c) second channel code decoding means for decoding said second part (S2) by using a code out of a second set of one or more channel codes, said second set comprising at least one second type of channel code (C_{pc}) being designed as a parity-check enabling code for realising a predefined parity-check constrained imposed on said parity-check segments (1, 7), wherein said parity-check constrained is related to a predetermined error event of said channel.

28. A device according to claim 27, wherein said first type channel signal segments (6) and said second type channel signal segments (7) constituting a repitition scheme of channel code (Cₛₜ, C_{sub}, C_{pc}),
a) first channel code decoding means are designed for decoding said first type channel signal segments (6) by using said first set of channel codes (Cₛₜ, C_{sub}), said first set further comprising a third type of channel code (C_{sub}), wherein
i) said first type of channel code (Cₛₜ) is used for decoding data bits of said channel words (3) into data bits of said user words (2) and
ii) said third type of channel code (C_{sub}) is used for converting data bits of said channel words (3) into data bits of said user words (2) and possibly for detecting DC-control information in said constrained binary channel signal (3), an wherein
b) second channel code decoding means are designed for decoding second type channel signal segments (7) by using said second set of channel codes, said second set comprising said first set of channel codes (Cₛₜ, C_{sub}) as well as said at least one second type of channel code (C_{pc}), and
c) said first and/or second channel code decoding means being designed to decode data bits of said channel word (3) relating to said first type channel signal segments (6) with said second type of channel code (C_{pc}) according to said repetition scheme.
